(19) United States
(12) Patent Application Publication
(10) Pub. No.: US 2006/0052250 A1
(43) Pub. Date: Mar. 9, 2006

(54) Superconductors with super high critical temperatures, methods for identification, manufacture and use

(76) Inventor: John Robert Schrieffer, Monticello, FL (US)

Correspondence Address: SHELDON & MAK, INC, 225 SOUTH LAKE AVENUE, 9TH FLOOR, PASADENA, CA, 91101, US

(21) Appl. No.: 11/127,682

(22) Filed: May 11, 2005

Related U.S. Application Data
(60) Provisional application No. 60/569,824, filed on May 11, 2004.
(60) Provisional application No. 60/570,123, filed on May 11, 2004.
(60) Provisional application No. 60/570,571, filed on May 13, 2004.
(60) Provisional application No. 60/570,797, filed on May 12, 2004.

(51) Int. Cl. H01L 39/24

(52) U.S. Cl. 505/473

(57) ABSTRACT

A new class of novel super high temperature superconductive compositions and structures (SHTC), named Schrieffer Superconductors are disclosed. These superconductive compositions and structures preferably include a combination of (1) a metal, the metal characterized in having (i) a broad conduction electron band (or bands) and (ii) a low effective mass, and (2) magnetic species, wherein the spins of the magnetic species are correlated at relatively long distances. Preferably, the spins of the magnetic species are magnetically ordered ferromagnetically over relatively long range. One preferred composition is Au₂Mn_{2-z}Al_{z} where 0.1<z<0.5, preferably 0.3.

### RELATED APPLICATIONS

The application claims the benefit of U.S. Provisional Application accorded Ser. No. 60/569,824, entitled “Structure and Materials Relating to Novel Superconductors With Extremely High Critical Temperatures, Manufacture, and Application”, filed May 11, 2004; U.S. Provisional Application accorded Ser. No. 60/570,123, entitled “Novel Superconductors With Extremely High Critical Temperatures, Structures including Same and Methods for Their Identification, Manufacture and Use”, filed May 11, 2004; U.S. Provisional Application accorded Ser. No. 60/570,571, entitled “Superconductive Structures and Materials, and Methods for Their Identification, Manufacture and Use”, filed May 13, 2004; and U.S. Provisional Application accorded Ser. No. 60/570,797, entitled “Novel Superconductors With Extremely High Critical Temperatures, Structures including Same and Methods for Their Identification, Manufacture and Use”, filed May 12, 2004; which are all incorporated herein by reference as if fully set forth herein.

### BACKGROUND

This application relates to superconductive materials, as well as useful devices incorporating superconductors. The application also relates to methods of identification of novel, extremely high temperature superconductors, and methods for their fabrication and use.

Superconductivity was first observed in mercury (Hg) in 1911 by Heike Kamerlingh Onnes of Leiden University. When he cooled mercury to the temperature of liquid helium, 4 degrees Kelvin, its resistance suddenly disappeared. In 1933 it was discovered that superconducting materials were also strong diamagnets, i.e., they will repel externally applied magnetic fields, an effect referred to as the Meissner effect. These two effects, loss of resistance and the Meissner effect, are the hallmarks of superconductivity. In subsequent decades superconductivity was discovered in many other superconducting metals, alloys and compounds. In 1941 niobium-nitride (NbN) was discovered to have a T_{c}=16 K.

The first widely accepted theoretical understanding of superconductivity was advanced in 1957 by American physicists John Bardeen, Leon Cooper, and one of us, J. Robert Schrieffer. The BCS theory (as it came to be known in recognition of the first letters of the last names) explained superconductivity at temperatures close to absolute zero for elements and simple alloys. Bardeen, Cooper and Schrieffer were awarded the Nobel Prize for this work in 1971. This understanding helped to direct efforts of researchers through the 1960's and early 1970's leading to the discovery of Nb₃Sn (T_{c}=18 K) and ultimately Nb₃Ge (T_{c}=23 K) in 1973. Efforts to find materials with higher T_{c}'s were largely disappointing.

Then, in 1986, Alex Müller and George Bednorz, researchers at the IBM Research Laboratory in Rtischlikon, Switzerland, created a brittle ceramic compound that superconducted at the highest temperature then known: T_{c}=30 K. The Lanthanum, Barium, Copper and Oxygen (LBCO) compound that Müller and Bednorz synthesized behaved in a not-as-yet-understood way. It was later found that tiny amounts of this material were actually superconducting at 58 K, due to a small amount of lead having been added as a calibration standard—making the discovery even more noteworthy.

Müller and Bednorz' discovery triggered a flurry of activity in the field of superconductivity with many researchers embarking on a quest for higher T_{c} materials. In January of 1987 a research team at the University of Alabama-Huntsville substituted Yttrium for Lanthanum in the Müller and Bednorz molecule and achieved an incredible T_{c} of 92 K. For the first time materials (today referred to as YBCO) had been found that have T_{c}'s greater than the boiling point of liquid nitrogen (77 K). Superconductivity above 77K has been observed in many cuprate materials including TBCCO and BiSCCO materials.

The current class (or “system”) of ceramic superconductors with the highest transition temperatures are the mercuric-cuprates. The first synthesis of one of these compounds was achieved in 1993. The world record T_{c} of 138 K is now held by a thallium-doped, mercuric-cuprate comprised of the elements Mercury, Thallium, Barium, Calcium, Copper and Oxygen. The T_{c} of this ceramic superconductor was confirmed by Dr. Ron Goldfarb at the National Institute of Standards and Technology-Colorado in February of 1994. Under extreme pressure its T_{c} can be coaxed up to 160 K at 300,000 atmospheres.

Since 1987, superconductivity above 15 K has been discovered in many other classes of materials. One such class is based on compounds centered around the spherical carbon 60 “Fullerene”. When doped with one or more alkali metals the fullerene becomes a “fulleride” and has produced T_{c}'s ranging from 8 K for Na₂Rb_{0.5}Cs₆₀ and 16 K of K₃C₆₀ up to 40 K for Cs₃C₆₀. In 1993 T_{c}'s between 60 K and 70 K were reported for C-60 doped with the interhalogen compound ICl. Superconductivity has also been reported at 15 K in non-spherical pure carbon fullerenes, and in Silicon-based fullerides such as Na₂Ba₆Si₄₆.

“Organic” superconductors are part of the organic conductor family which includes: molecular salts, polymers and pure carbon systems (including carbon nanotubes and C₆₀ compounds). The molecular salts within this family are large organic molecules that exhibit superconductive properties at very low temperatures. For this reason they are often referred to as “molecular” superconductors. Their existence was theorized in 1964 by Bill Little of Stanford University. But the first organic superconductor (TMTSF)₂ PF₆ was not actually synthesized until 1980 by Danish researcher Klaus Bechgaard of the University of Copenhagen and French team members D. Jerome, A. Mazaud, and M. Ribault. About 50 organic superconductors have since been found with T_{c}'s extending from 0.4 K to near 12 K (at ambient pressure). Since theses T_{c}'s are in the range of Type I superconductors, engineers have yet to find a practical application for them. However, their rather unusual properties have made them the focus of intense research. These properties include giant magnetoresistance, rapid oscillations, quantum hall effect, and more (similar to the behavior of InAs and InSb). In early 1997, it was, in fact (TMTSF)₂PF₆ that a research team at SUNY discovered could resist “quenching” up to a magnetic field strength of 6 tesla. Ordinarily, magnetic fields a fraction as strong will completely kill superconductivity in a material.

Organic superconductors are composed of an electron donor (the planar organic molecule) and an electron acceptor (a non-organic anion). Below are a few more examples of organic superconductors.
(TMTSF)₂ClO₄ [tetramethyltraselenafulvalene+acceptor]
(BETS)₂GaC₁₄ [bis(ethylenedithio)tetraselenafulvalene+acceptor]
(BEDO-TTF)₂ReO₄H₂O [bis(ethylenedioxy)tetrathiafulvalene+acceptor]

Discovered in 1993, the “Borocarbides” are one of the least-understood superconductor systems of all, since it has long been assumed that superconductors could not be formed from ferromagnetic transition metals—like Fe, Co or Ni.

It is believed that the crystallographic sites for the magnetic ions are thought to be isolated from the conduction path in the borocarbide superconductors allowing Cooper pairs to detour around the magnetic ions. Further, when combined with an element that has unusual magnetic properties—like holmium—“re-entrant” behavior can also be in evidence in some borocarbides. Below T_{c}, where it should remain superconductive, there is a discordant temperature at which the material retreats to a “normal’, non-superconductive state. The record T_{c} for this class of materials is currently held by YPd₂B₂C at T_{c}=23 K. The first all-metal perovskite superconductor MgCNi₃ (T_{c}=8 K) discovered in 2001 also falls loosely into this class.

The “Heavy Fermions” are yet another example of atypical superconductors. Heavy fermions are compounds containing rare-earth elements such as Ce or Yb, or actinide elements such as U. Their (inner shell) conduction electrons often have effective masses resulting in what is known as low “Fermi energy” (Ef). This makes them reluctant superconductors. Yet, at cryogenic temperatures, many of these materials are magnetically ordered, others show strong paramagnetic behavior, and some display superconductivity through a mechanism that quickly runs afoul of BCS theory. Research suggests Cooper pairing in the fermion systems arises from the magnetic interactions of the electron spins (d-wave, p-wave, s-wave), rather than by lattice vibrations. The first observation of superconductivity in a heavy fermion system was made by E.

Bucher, et al, in 1973 in the compound UBe₁₃: but, at the time was attributed to precipitated uranium filaments. Superconductivity was not actually recognized, per se, in a heavy fermion compound until 1979 when Dr. Frank Steglich of the Max Planck Institute for Chemical Physics in Solids (Dresden, Germany) realized it was a bulk property in CeCu₂Si₂.

In April 2003 a heavy-fermion compound unambiguously exhibited the so-called “FFLO” state, where magnetism and superconductivity have a beneficial coexistence. The compound CeCoIn₅ (the first confirmed FFLO compound) confirmed a theoretical model first put forth in 1964 by Fulde, Ferell, Larkin, and Ovchinnikov (FFLO). Table 1 lists some heavy fermion compounds that will superconduct, along with their T_{c}'s. As can be seen, their transition temperatures are in the range of Type I superconductors, which severely limits their usefulness.

TABLE 1

| Compound | T_{c} (K) |
|---|---|
| CeCoIn₅ | 2.3 |
| UPd₂A₁₃ | 2 |
| Pd₂SnYb | 1.79 |
| URu₂Si₂ | 1.2 |
| UNi₂Al₃ | 1 |
| Al₃Yb | 0.94 |
| UBe₁₃ | 0.87 |
| CeCo₂ | 0.84 |
| UPt₃ | 0.48 |
| CeCu₂Si₂ | 0.1-0.7 |

Note that UGe₂ and URhGe₂ exhibit simultaneous ferromagnetism and superconductivity.

In the mid 1990's, it was discovered that copper-oxygen planes are not the only superconducting facilitators within the layered perovskites. In 1994 it was discovered that the compound Sr₂RuO₄ exhibited superconductivity at 1.5 K. While this is an extremely cold T_{c} for a superconducting perovskite, it revealed a new area of potential among a class of materials known as “Ruthenates”. Shortly after that SrRuO and SrYRuO₆ were also found to be superconductors at similar low temperatures.

Ruthnocuprates such as RuSr₂(Gd,Eu,Sm)Cu₂O₈ (or any parenthetical element partially substituted by Y) are a class of materials whose bulk is both a superconductor and a magnet. Although it was not the first compound discovered that exhibits coexisting ferromagnetism and superconductivity, its remarkably high T_{c} of 58 K makes it truly distinct in the world of superconductors. Unlike “normal” superconductors, this compound only becomes diamagnetic at about one-half T_{c}.

Hints of superconductivity have been found in other surprising classes of materials. In July of 1999 near 91 K was reported in the sodium-doped tungsten-bronze Na_{0.05}WO₃. This would be the first known HTS with a T_{c}>77K that is not a cuprate. Most tungsten-bronze compounds that are known to superconduct have T_{c}'s below 4 K—making this a truly tantalizing find. Other categories of materials that theory suggests may produce fluoroargentates. Fluoroargentates bear a strong similarity to cuprates. In October 2003 sudden drops in magnetic susceptibility within a large number of samples of Be—Ag—F were reported. This observation was attributed to possible spherical regions of superconductivity—with a T_{c} up to 64 K—couched inside a ferromagnetic host.

With few exceptions (e.g., polysulphur-nitrides), most polymers resist being coaxed into a superconductive state. However, some organic polymers exhibit electrical resistance many orders of magnitude lower than the best metallic conductors. And, they do this at room temperature! These ultraconductors™, materials such as oxidized atactic polypropylene (OAPP), do not have zero resistance. But, their enhanced conductivity at ambient temperatures and pressures may actually allow them to compete with superconductors in certain fields. Polypropylene, for example, is normally an insulator. In 1985, however, researchers at the Russian Academy of Sciences discovered that as an oxidized thin-film, polypropylene can have a conductivity 105 to 106 higher than the best refined metals. The Meissner effect—the classic criterion for superconductivity—cannot be observed, as the critical transition temperature appears to be above the point at which the polymer breaks down (>700K). However, strong (giant) diamagnetism has been confirmed.

Applications of low T_{c} superconductivity (LTS) have been few and limited by the need for extreme low temperatures, most practically achieved using liquid Helium as a cryogen. However, one application in particular has achieved broad applicability. Various LTS materials have been made into wires used in electromagnets to generate the large magnetic fields required for nuclear magnetic resonance and magnetic resonance imaging systems. Unfortunately the need for extreme low temperatures has made these wires unattractive for many other applications where they could be useful.

Applications of the HTS cuprate materials have also been limited, but unlike the LTS materials most of these limitations arise from the complexity inherent in the materials. Being ceramics, the HTS cuprates are not so easily formed into long, flexible lengths of wire. Furthermore, the ideal properties of HTS materials are fairly easily degraded if the material is not close to behaving as a single crystal. In the case of wires, the driving parameter has been to maintain J_{c} (the critical current density of the superconducting material). HTS cuprate wires have been made in ˜1000 meter lengths using BiSCCO filaments in a Ag matrix, and recent techniques such as IBAD (ion beam assisted deposition) and RABiTS (rolling-assisted, biaxially-textured substrates) will likely enable a new generation of YBCO and other HTS cuprate wires.

Epitaxil thin films of HTS cuprate materials such as YBCO and TBCCO as well as thick films of YBCO have also successfully been used to make self-contained microwave and radio frequency filter systems that can be used to improve the sensitivity of cellular telephone and other wireless systems. These required the development of a new class of compact and reliable cryocoolers as well as significant materials development to maintain ideal properties over sufficiently large areas. For microwave circuits the parameters in question are primarily the surface resistance (Rs) and the nonlinear microwave critical current density (j_{IMD}). These developments have also been shown to be useful in developing receive antennas which can improve the sensitivity of NMR and MRI systems.

Many devices making use of the Josephson effect, such as SQUIDs (Superconducting Quantum Interference Devices) have also been proposed and developed, in diverse areas such as non-destructive evaluation, microscopy, magnetocardiography and magnetoencephalography, A/D and D/A converters, amplifiers, computing, etc. but none has really achieved broad applicability due to the fact that processes to make repeatable Josephson junction in the HTS cuprates have proven elusive and LTS (where repeatable junction processes have recently been developed) still requires extremely low temperatures.

### SUMMARY

The properties of a wide variety of intermetallic compounds exhibiting magnetic localized spin and superconducting fluctuations near a quantum critical point are reviewed. They show highly anomalous critical indices (anomalously small). Laws of corresponding are observed in these materials and a theory is presented which gives a fully quantitative explanation of these laws. The theory employs a gauge transformation which rotates the electron spin quantization axis z into the direction of the instantaneous staggered localized spin direction \vec{M}(\vec{r},t)=\vec{M}₀(\vec{r},t)cos \vec{Q}·\vec{r}, where \vec{Q} is the localized spin array wave vector. Many properties of these materials are worked out on the basis of this theory. The technological promise of these substances is truly immense, including energy generation, storage and transmission, MRI magnets, industrial and scientific magnets, maglev, cellular communications, μ-wave electronics, etc.

A new class of novel super high temperature superconductive compositions and structures (SHTC), which we have named Schrieffer Superconductors are disclosed. These superconductive compositions and structures preferably include a combination of (1) a metal, the metal characterized in having (i) a broad conduction electron band (or bands) and (ii) a low effective mass, and (2) magnetic species, wherein the spins of the magnetic species are correlated at relatively long distances. Preferably, the spins of the magnetic species are magnetically ordered ferromagnetically over relatively long distances.

The compositions and structures have a ratio of the exchange interaction between the free electrons and the spins (J) and the bandwidth of the free electrons (W) in the range from substantially 0.5≦J/W≦5. While the range from substantially 0.5≦J/W≦5 is preferred, the range from 0.7 to 3 is more preferred.

Various compositions are disclosed. One preferred Schrieffer Superconductor composition is Au₂Mn_{2-z}Al_{z} where 0.1<z<0.5, preferably 0.3. Alternately, this can be represented as Au₂(MnₓAl_{y})₂ where x+y is substantially 1, and 0.05<y<0.25, preferably 0.15.

### DRAWINGS

FIG. 1 is a Feynman diagram of the Gor'kov self energy Σ(k,ωₙ,T) in the one loop approximation.

FIG. 2 is a phase diagram of the t−J model.

FIG. 3 is a Feynman diagram of the RPA Grand canonical potential Λ_{RPA}(T).

FIG. 4 is a perspective view of a crystal structure of a Heusler-related alloy.

FIG. 5 is a perspective view of a crystal structure of a Laves-related alloy.

FIG. 6 is a plot of T_{Neel} as a function of Z content.

### DETAILED DESCRIPTION

1. Introduction

The critical indices corresponding to the spin susceptibility χ(\vec{Q},ω,T), in a large number of ferromagnetic and antiferromagnetic intermetallic compounds and the specific heat C_{V}(T), as well as many other quantities, exhibit critical indices which are highly anomalous (i.e., exceedingly small). For example, it is found that near the quantum critical point (QCP),
χ(\vec{Q},ωₙ=0,T)∝1/T^{γ}, γ≅0.14. (1)

Also, the specific heat C_{V}(T) is found to obey
C_{V}(T)∝ln(T/T₀), (2)
over a wide range of T/T₀ about the QCP. Thus a law of corresponding states exists.

It is known that in a mean field approach:
χ₀(\vec{Q},ωₙ=0,T)∝1/(T−T_{N}) (3)
and
C_{0V}(T)∝T. (4)

Hertz[3], in his pioneering studies of the QCP in ferromagnetic materials, used a fermion functional integral action S_{H} worked out to fourth order in the spin fluctuation field (i.e., the one fermion loop level) and found highly anomalous critical indices near the QCP, although he did not investigate χ and C_{V}. In later studies, Millis [4] confirmed Hertz's results in a calculation at a higher loop level. Further studies [5] to [11], excluding the present work, have shed little additional light on these remarkable phenomena.

For clarity, we study the spin fermion model:

$${H ( t )}_{SF} = - {\sum }_{ijs} {t}_{ij} {ψ}_{is}^{†} {ψ}_{js} + J {\sum }_{{iss}^{′}} {ψ}_{is}^{†} {ψ}_{{is}^{′}} {{σ}^{->}}_{{ss}^{′}} \cdot {S}_{i} ( t ) , \qquad ( 5 )$$

where ψ^{†}, ψ and \vec{S} satisfy
{ψᵢₛ^{†},ψ_{js′}}=δᵢⱼδ_{ss′} (6)
and
[S_{iα},S_{jβ}]=iS_{γ}δᵢⱼ, (7)
with α, β and γ being related cyclically.

These anomalous phenomena have been explored in the Hubbard model and nearly identical results to those presented here are found, although the analysis is far more complex.

To carry through the analysis, we exploit the slow spatial and temporal variation of the critical degrees of freedom near the QCP. By making a WKB-like adiabatic unitary transformation U(t), which rotates the electron-spin quantization axis \hat{z} to that of the direction of the local instantaneous staggered magnetization,
\overline{M}ᵢ(t)≡cos \vec{Q}·\vec{r}ᵢ\vec{S}ᵢ(t), (8)
we obtain rapid convergence of all observable quantities, near the QCP, such as χ(T), C_{V}(T), etc. We find excellent agreement of all observable quantities with experiment, and herein apply it to many experimental observables.
2. Spin-Rotation Transformation

We define the unitary electron-spin rotation operator U(t) as:

$$U ( t ) = T {ⅇ}^{\frac{i}{2} {\sum }_{{iss}^{′}} {ψ}_{is}^{†} ( t ) {{σ}^{->}}_{{ss}^{′}} \cdot {{Ω}^{->}}_{i} ( t ) {ψ}_{{is}^{′}} ( t )} \qquad ( 9 )$$

Here \vec{Ω}ᵢ(t) is the vector electron spin rotation angle, defined by

$${{Ω}^{->}}_{i} ( t ) = {sin}^{- 1} \vert \hat{z} \times {{M}^{->}}_{i} ( t ) \vert \cdot \frac{\hat{z} \times {{M}^{->}}_{i} ( t )}{\vert \hat{z} \times {{M}^{->}}_{i} ( t ) \vert} \qquad ( 10 )$$

Making the transformation,
\overline{H}(t)=U^{†}(t)HU(t), (11)
we find
\overline{H}(t)=H₀(t)+H_{sdp}(t)+H_{dia}(t)+\overline{H}_{J}(t), (12)
where H₀(t) is given by the electron hopping in the rotated basis \overline{s}, by

$${H}_{0} ( t ) = - {\sum }_{ij \overline{s}} {t}_{ij} {ψ}_{i \overline{s}}^{†} {ψ}_{j \overline{s}} . \qquad ( 13 )$$

We find H_{sdp} is given by

$${H}_{sdp} ( t ) = - {\sum }_{{iss}^{′}} {t}_{ij} {ψ}_{is}^{†} ( t ) {{σ}^{->}}_{{ss}^{′}} \cdot {{∇}^{->}}_{i} {ψ}_{{is}^{′}} ( t ) \cdot [ {{∇}^{->}}_{{r}_{i}} {Ω}^{->} ( {r}_{i} , t ) + {Ω}^{->} ( {{r}^{->}}_{i} , t ) {{∇}^{->}}_{{r}_{i}} ] , \qquad ( 14 )$$

H_{sdp} is the spin deformation potential, analogous to the electron-phonon deformation potential Hₑₗ₋ₚₕ in solids [15],

$${H}_{el - ph} ( t ) = {\sum }_{is λ} {g}_{λ} {ψ}_{is}^{†} ( t ) {ψ}_{js} ( t ) ( {{r}^{->}}_{i} - {{r}^{->}}_{j} ) \cdot {∇}^{->} {{u}^{->}}_{i} ( t ) \cdot {\hat{ɛ}}_{λ i} \qquad ( 15 )$$

where (\vec{r}ᵢ−\vec{r}ⱼ)·\vec{∇}\vec{u}ᵢ(t)·\hat{ε}_{λi} is the local lattice dilation and g_{λ} is the electron-phonon deformation potential constant (units of energy/length where λ) which is typically of order 1-4 eV/A in solids.

In addition, there is a diamagnetic-like coupling

$${H}_{dia} ( t ) = {\sum }_{is} {t}_{ij} {ψ}_{is}^{†} ( t ) {ψ}_{is} t ) {\vert {∇}_{i} {{Ω}^{->}}_{i} ( t ) \vert}^{2} , \qquad ( 16 )$$

similar to the A² term of QCD. For a free electron band, H can be written as

$$\overline{H} ( t ) = - \frac{{ℏ}^{2}}{2 m} {\sum }_{s} \int ⅆ {r}^{->} {ψ}_{s}^{†} ( r , t ) {∇}^{2} {ψ}_{s} ( {r}^{->} , t ) - \frac{{ℏ}^{2}}{2 m} {\sum }_{{ss}^{′}} \int ⅆ {r}^{->} {ψ}_{s}^{†} ( {r}^{->} , t ) {{σ}^{->}}_{{ss}^{′}} \cdot {∇}^{->} {ψ}_{{s}^{′}} ( {r}^{->} , t ) \cdot [ {∇}^{->} {Ω}^{->} ( {r}^{->} , t ) + {Ω}^{->} ( r , t ) {∇}^{->} ] + {\sum }_{s} \int ⅆ {r}^{->} {ψ}_{is}^{†} ( {r}^{->} , t ) {ψ}_{j} ( {r}^{->} , t ) {\vert ∇ Ω ( t ) \vert}^{2} + J {\sum }_{{\overline{s}}_{{\overline{s}}^{′}}} \int ⅆ {r}^{->} {ψ}_{\overline{s}}^{†} ( {r}^{->} , t ) {{σ}^{->}}_{{\overline{s}}_{{\overline{s}}^{′}}} \cdot {S}^{->} ( {r}^{->} , t ) {ψ}_{{\overline{s}}^{′}} ( {r}^{->} , t ) , \qquad ( 17 )$$

where \overline{s} is quantized along the instantaneous staggered magnetization \vec{M}(\vec{r}, t). More compactly, \overline{H} can be written as

$$\overline{H} ( t ) = - \frac{{ℏ}^{2}}{2 m} {\sum }_{{ss}^{′}} \int ⅆ {r}^{->} {ψ}_{s}^{†} ( r , t ) ( {∇}^{->} {δ}_{{ss}^{′}} + i {{A}^{->}}_{{ss}^{′}} ( {r}^{->} , t ) ) ( ∇ {δ}_{{ss}^{′}} {t}_{i} {{A}^{->}}_{{ss}^{′}} ( {r}^{->} , t ) ) {ψ}_{s} ( {r}^{->} , t ) + J {\sum }_{\overline{s}} \int ⅆ {r}^{->} {ψ}_{\overline{s}}^{†} {σ}_{\overline{S} \overline{ss}} {ψ}_{\overline{s}} {S}_{\overline{S}} ( {r}^{->} , t ) , \qquad ( 18 )$$

where \vec{A}_{ss′}(\vec{r},t) is defined by
\vec{A}_{ss′}(\vec{r},t)≡\vec{σ}_{ss′}·(\vec{∇}\vec{Ω}(\vec{r},t)+\vec{Ω}(\vec{r},t)\vec{∇}). (19)

It is H_{sdp} and H_{dia} that lead to the anomalous critical indices near the QCP. While the discussion to this point is exact it is useful to make the pairing correlations explicit by introducing the Gor'kov two component spinor Ψₛ^{†}(r,t) [13] defined by
Ψₛ^{†}(\vec{r},t)=[ψₛ^{†}(\vec{r},t),ψ₋ₛ(\vec{r},t)]. (20)

We introduce the Pauli pseudo spin matrices,
τᵢ=0,1,2,3 (21)
where τ₀ is the unit pseudo-spin matrix.

It is straightforward to see that the electrons couple to the charge and spin through the vertices τ₃ for charge and τ₀ for spin.[13] All of the calculations are manifestly gauge invariant, as opposed to the original BCS calculations.

3. T_{c} and the Gap Equation

As in BCS, T_{c} is determined by the linearized gap equation. The first remarkable fact is that H_{sdp} leads to p-wave (l=1, s=1) pairing for ferromagnetic spin fluctuations, at a remarkably high temperature of order T_{c}≅30,000° K. H_{dia} and \overline{H}_{J} lead to d-wave (l=2, s=0) and s-wave (l=0, s=0) pairing, as in the work of Scalapino and of Pines, where \overline{H}_{J} plays the role of the weak electron-phonon coupling. As we will see below, T_{c} is highest for p-wave (l=1, s=1) pairing and it should be readily observed in electron tunneling, ARPES, C_{V}(T), χ(Q,ω,T) neutron scattering measurements, Raman, IR, λ(T), K_{T}(T), etc. These and many other measurements should show highly anomalous properties near the QCP.

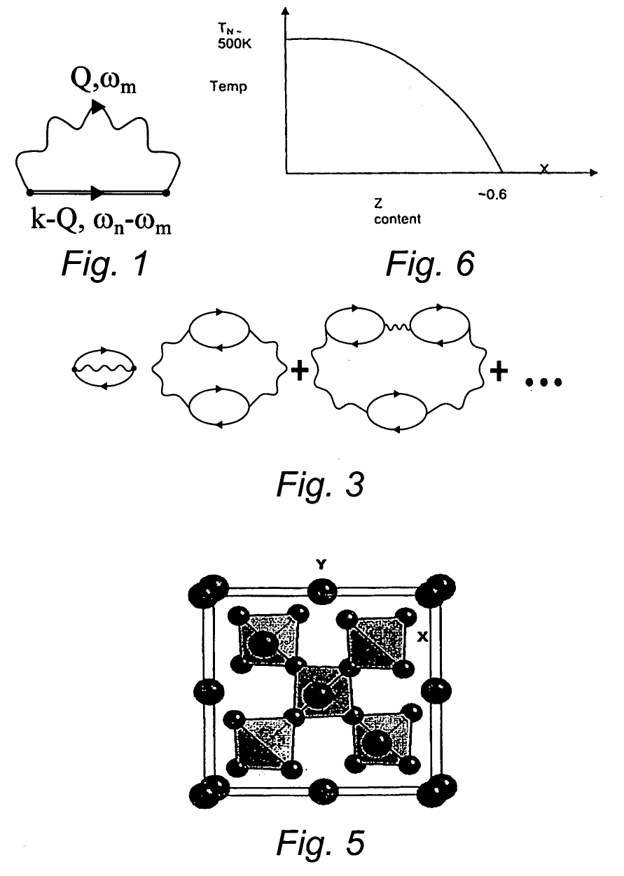

With reference to FIG. 1, the Gor'kov one electron self energy is given at the one loop level by

$$\sum ( {k}^{->} , {ω}_{n} , {T}_{c} ) = - {\sum }_{Q , {ω}_{m}} [ V ( {Q}^{->} , {ω}_{n} , T ) G ( {k}^{->} + {Q}^{->} , {ω}_{n} - {ω}_{m} , T ) ] , \qquad ( 22 )$$

where V is the pairing interaction arising from H_{sdp}, H_{dia}, and \overline{H}_{J}, with ωₙ=2nπk_{B}T and ωₘ=(2m+1)πk_{B}T. The gap equation [13] is given for the complex pairing order parameter Δ(\vec{k},ωₙ,T) by

$$\begin{matrix}Δ ( \vec{k} , {ω}_{n} , T ) = - {\sum }_{Q , {ω}_{m}} \frac{1}{Z ( \vec{k} , {ω}_{n} , T )} & ( 23 ) \\ {[ V ( \vec{Q} , {ω}_{m} ) G ( \vec{Q} + \vec{k} , {ω}_{n} - {ω}_{m} , T ) ]}_{12} & \end{matrix}$$

The normal state renormalization function Z(\vec{k},ωₙ,T) is given by [13]

$${ⅈω}_{n} Z ( k , {ω}_{n} , T ) = - \frac{1}{2} {\sum }_{{}^{{}_{Q , {ω}_{m}}^{\to }}} {[ V ( \vec{Q} , {ω}_{m} , T ) G ( \vec{k} + \vec{Q} , {ω}_{n} - {ω}_{m} , T ) ]}_{11 + 12} \qquad ( 24 )$$

and the renormalized kinetic energy \overline{ε} defined by
\overline{ε}(k,ωₙ,T)≡εₖ+χ(k,ωₙ,T), (25)
where \overline{χ} is given by

$$\tilde{χ} ( k , {ω}_{n} , T ) = - \frac{1}{2} {\sum }_{{Qω}_{m}} [ V ( Q , {ω}_{m} , T ) {G ( k + Q , {ω}_{n} + {ω}_{m} , T ]}_{11 - 12} . \qquad ( 26 )$$

4. Super-High T_{c} (SHTC)

For the p-wave (l=1, s=1) phase T_{c} is given for a square potential model [13] as

$$\begin{matrix}{k}_{B} {T}_{c} = 1.14 {ω}_{s} {e}^{- \frac{1 + {λ}_{Z}}{{λ}_{V}}} where & ( 27 ) \\ ℏ {ω}_{s} = \frac{{J}^{2}}{W} & ( 28 )\end{matrix}$$

is the spin fluctuation frequency. The renormalization constant λ_{Z} for l=1 is zero due to the p-wave character of the potential in Equation (24), and

$${λ}_{v} = {( \frac{W}{J} )}^{2} . \qquad ( 29 )$$

Maximizing T_{c} for fixed W, we find

$$\begin{matrix}{( {k}_{B} {T}_{c} )}_{max} = 1.14 \frac{{J}^{2}}{W} {e}^{- \frac{1}{{λ}_{V , max}}} , \text{with} & ( 30 ) \\ {λ}_{V , max} = \frac{{W}^{2}}{{J}^{2}} = 1. & ( 31 ) \\ For W = 10 ⅇ V , {T}_{c max} \text{is given by,} & \\ {T}_{c} = 1.14 {We}^{- 1} ≃ 30 \text{,0} 00 K & ( 32 )\end{matrix}$$

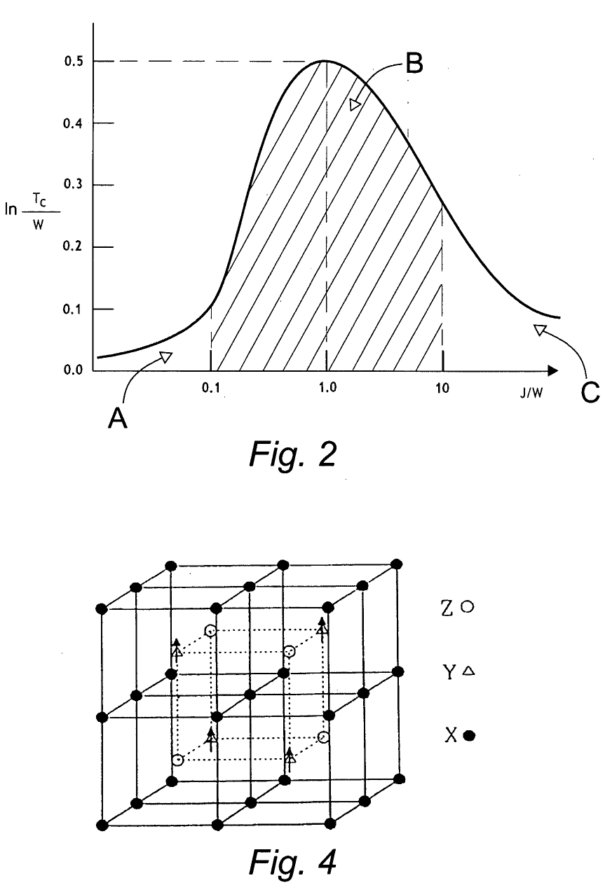

With reference to FIG. 2, plotting log T_{c}/W vs. J/W we find T_{c} remains relatively stable for 0.5≦J/W≦5. This gives the advantage that T_{c} is highly insensitive to impurity concentration, fluctuations, etc., a fact of great importance in technological as well as scientific applications of SHTC. For J/W>5, one enters the Kondo spin compensated regime.

FIG. 2 is a phase diagram of the t−J model, showing the conventional nearly antiferromagnetic fermi liquid of Scalapino and Pines valid for J≦0.5 W, where J is the electron localized spin exchange coupling and W is the electronic band width. Region A is the Scalapino Pines HTS theory regime. The pairing interaction is due to exchange of spin fluctuations with coupling J, leading to d-wave pairing (2, s=1). For Region B, where 0.5 W≦J≦5 W, a novel p-wave, (l=1, s=1) phase is predicted with an extremely high T_{C} of immense technological importance. In this phase the existence of Leggett-like collective modes is predicted, corresponding to an oscillation at frequency ω_{L} of the angle between \vec{L} and \vec{s} of a pair. However, here the novel strong spin deformation raises ω_{L} to a high value near IR range vs the low frequency of superfluid ³He, where the spin orbit coupling Hₛₒ is extremely weak. The interaction is due to (a) spin deformation potential with p-wave gap and d-wave or s-wave, (b) a lower T_{c} phase due to H_{dia} and H_{J}.

5. Thermodynamics

The grand potential Λ(T) is given by
Λ(T)=−k_{B}TlnTrTe^{-β(\overline{H}-μN}^{ₑₗ}⁾ (33)
where μ is the electrochemical potential. C_{V}(T) is given by

$${C}_{v} ( T ) = - \frac{ⅆ}{ⅆ T} Λ ( T ) \qquad ( 34 )$$

Within the random phase approximation, Λ(T), with reference to FIG. 3, is given by

$$\begin{matrix}{Λ}_{RPA} ( T ) = - \frac{1}{2} {\sum }_{{}_{Q , {ω}_{n} , s}^{\to }} TrV ( \vec{Q} , {ω}_{n} , T ) \\ {Φ}_{0} ( \vec{Q} , {ω}_{n ,} T ) [ 1 - \frac{1}{2} TrV ( \vec{Q} , {ω}_{n} , T ) & ( 35 ) \\ {{Φ}_{0} ( \vec{Q} , {ω}_{n} , T ) ]}^{- 1} & \end{matrix}$$

The zeroth order irreducible polarizability is defined by

$${Φ}_{0} ≡ - 2 {\sum }_{k , {ω}_{m}} {G}_{0} ( \vec{k} + \vec{Q} , {ω}_{n} + {ω}_{m} , T ) {G}_{0} ( \vec{k} , {ω}_{n} , T ) , \qquad ( 36 )$$

where the factor of 2 arises from the spin sum in the fermion loop.
6. Electron Tunneling, ARPES Measurements and Collective (Leggett) Modes

As Bardeen showed, the Giaever differential tunnelling conductance is given by

$$\frac{ⅆ I}{ⅆ V} ∝ {ImG ( \vec{k} , ⅇ V , T )}_{11 + 12} , \qquad ( 37 )$$

This should show p-wave (l=1, s=1) pseudogap behavior in the SHTC phase.

The ARPES differential cross section is given by

$$\frac{ⅆ σ}{ⅆ \vec{k} ⅆ ω} ∝ {ImG ( k , ω , T )}_{11 + 22} , \qquad ( 38 )$$

and should demonstrate p-wave (l=1, s=1) pseudogap behavior, as will the London penetration depth λ(T).

As in superfluid ³He-A, there exist six “Leggett collective modes.” In superfluid ³He-A, these are degenerate, however, due to the exchange coupling,

$$\frac{J}{2} {\sum }_{{\overline{s}}_{\overline{s}}} \cdot {\vec{S}}_{\overline{s}} ( \vec{r} , t ) \cdot {ψ}_{\overline{is}}^{†} {\vec{σ}}_{\overline{s} , \overline{ss}} {ψ}_{\overline{is}}^{†} {ψ}_{i \overline{s}} , ( t ) ,$$

these modes are split due to \overline{H}_{J}. The spin-orbit interaction is given by

$${H}_{SO} ( t ) = \frac{{λ}_{SO} ℏ}{2 ⅈ} {\sum }_{{ss}^{′}} \int ⅆ \vec{r} {ψ}_{s}^{†} ( \vec{r} , t ) \vec{r} \times \vec{∇} {σ}_{{ss}^{′}} {ψ}_{s} ( \vec{r} , t ) . \qquad ( 39 )$$

Typically, 0.2< [symbol] λ_{SO}<2 eV in metals.

From the rotational invariance of \overline{H}(t)≡Hₒ+H_{sdf}(t)+H_{dia}(t) with respect to \vec{r} and spin, one may write

$$\begin{matrix}\begin{matrix}{H}_{SO} ( t ) = \frac{{λ}_{SO} {ℏ}^{3}}{2} \int {d \vec{r} \sum }_{l , s} {ψ}_{s}^{†} ( \vec{r} , t ) {ψ}_{s} ( \vec{r} , t ) \times [ j ( j + 1 ) - l ( l + 1 ) - s ( s + 1 ) ] , \\ \text{where} \\ l = 0 , 1 , 2 ⋯ , s = \pm 1 / 2 and j ( l , s ) = l \pm s = l \pm 1 / 2. Then\end{matrix} & ( 40 ) \\ {\overline{H}}_{SO} ( t ) = \frac{{λ}_{SO} {ℏ}^{3}}{2} {\sum }_{l , s} \int ⅆ \vec{r} {ψ}_{\overline{s}}^{†} ( \vec{r} , t ) {ψ}_{\overline{s}} ( \vec{r} , t ) \times [ j ( j + 1 ) - l ( l + 1 ) - s ( s + 1 ) ] , & ( 41 )\end{matrix}$$

where the electron-spin quantization axis for \overline{s} is along \vec{M}(\vec{r},t), as above. We define the state with one collective mode jls as

$${Ψ}_{jls} ( \vec{r} , t ) = {N}_{jls} \sum {Y}_{lm} ( {\vec{Ω}}_{l m} {X}_{sl} ( {δ}_{s , l + 1 / 2} - {δ}_{s , l - 1 / 2} ) {Ψ}_{0} ( t ) \qquad ( 42 )$$

where Nⱼₗₛ, normalizes Ψⱼₗₛ(t) to unity.

The energies of the collective modes, now diagonal in the jls basis, are given by

$${E}_{jls} = \frac{{λ}_{SO} {ℏ}^{3}}{2} [ j ( j + 1 ) - l ( l + 1 ) - 3 / 4 ] + {JS}_{\overline{S}} \cdot {s}_{\overline{S}} \qquad ( 43 )$$

with s_{\overline{S}}=±½. Thus, Eⱼₗₛ is given by

$$\begin{matrix}\frac{λ ℏ}{2} + \frac{J}{2} \overline{M} \overline{s} , \overline{s} = \pm 1 / 2 & ( 44 ) \\ {E}_{jls} = \{ - λ {ℏ}^{3} + \frac{J}{2} \overline{M} \overline{s} , \overline{s} = \pm 1 / 2 & ( 45 ) \\ - λ {ℏ}^{3} \overline{s} = \pm 1 / 2 , & ( 46 )\end{matrix}$$

where \overline{M} is the staggered magnetization. Observation of these modes in the near IR will give added proof of p-wave pairing in the presence of ferromagnetic spin fluctuations near the QCP.
7. Magnetic Spin Susceptibility and Neutron Scattering

The dynamic electronic spin susceptibility is given by

$$χ {( \vec{Q} , {ω}_{m} , T )}_{αβ} = {μ}_{β} {\sum }_{{kss}^{′} {ω}_{n}} {Ψ}_{s}^{†} ( \vec{k} + \vec{Q} , {ω}_{n} + {ω}_{m} ) \\ {\vec{σ}}_{{α ss}^{′}} {Ψ}_{s} ( \vec{k} , {ω}_{n} , T ) {Ψ}_{\vec{s}}^{†} ( k - Q , {ω}_{n} - {ω}_{m} ) {\vec{σ}}_{β \vec{ss}} {Ψ}_{\vec{s}} ( k , {ω}_{n} ) \qquad ( 47 )$$

The results of the present theory agree very well with the observed neutron scattering spectra.
8. Acoustic Attenuation

The acoustic attenuation rate is given by

$${α}_{λ} ( \vec{Q} , {ω}_{m} ) = - {g}_{λ}^{2} {\sum }_{k , {ω}_{n} , s , {s}^{′} , \vec{s} , \vec{s}} Im Tr [ {τ}_{3 {ss}^{′}} \\ {G}_{{ss}^{′}} ( \vec{k} + \vec{Q} , {ω}_{n} + {ω}_{m} , T ) {τ}_{3 \vec{ss}} \\ {G}_{\vec{ss}} ( \vec{k} , {ω}_{n} , T ) ] . \qquad ( 48 )$$

α should show power law T behavior at low T corresponding to the pseudo gap behavior of the p-wave (l=1, s=1) phase.
9. NMR

The 1/T NMR relaxation rate of p-wave l=1, s=1 pairing is given by

$$\frac{1}{{T}_{1}} ∝ {lim}_{ω \to 0} Im \frac{χ ( Q , ω , T )}{ω} {coth}^{- 1} ( ω \text{/} {k}_{B} T ) . \qquad ( 49 )$$

1/T₁ should also show p-wave l=1, s=1 pairing analogous to the power law behavior observed for the d-wave, l=2, s=0 pairing of conventional high temperature superconductors.
10. IR and Optical Absorption plus the Electronic Raman Scattering

The complex dynamic electromagnetic conductivity is given by

$$\begin{matrix}{σ}_{α β} ( \vec{Q} , {ω}_{n} , T ) = - {{ⅇ}^{2} ( \frac{{ℏ}^{2}}{2 m} )}^{2} \int ⅆ t ⅆ {t}^{′} {\sum }_{{ss}^{′} {\overline{ss}}^{′} k} \\ 〈 T [ {Ψ}_{s}^{†} ( \vec{k} + \vec{Q} t ) {τ}_{3} {ss}^{′} {Ψ}_{{s}^{′}} ( \vec{k} , t ) {Ψ}_{\overline{s}}^{†} ( \vec{k} - \vec{Q} {t}^{′} ) {Ψ}_{{\overline{s}}^{′}} ( \vec{k} , {t}^{′} ) ] 〉 {ⅇ}^{ⅈ {ω}_{n} ( t - {t}^{′} )} .\end{matrix} \qquad ( 50 )$$

This function should also show power law pseudo gap behavior, characteristic of p-wave (l=1, s=1) pairing.

11. Properties and Applications

The observable properties of the novel SHTC materials are as described. These materials are predicted to exhibit highly anomalous behavior, in that 1) the critical indices are highly anomalous (being small) near the QCP, 2) the properties should show power law T dependence at low T, reflecting p-wave, (l=1, s=1) pairing with a tremendously high T_{c}≧30,000° K, and 3) six Leggett modes should be seen in the near IR spectrum.

The potential for applications of SHTS to electric power generation, storage and transmission, MRI, maglev, industrial and scientific magnets and μ-wave electronics should be tremendous. Since these materials involve coupled pairing and magnetic spin fluctuations, highly nonlinear electrodynamic properties should be observed, with applications in communication, computers, etc.

Schrieffer Superconductors

The inventions herein relate to a new class of novel super high temperature superconductive compositions and structures (SHTC), which we have named Schrieffer Superconductors. These superconductive compositions and structures preferably include a combination of (1) a metal, the metal characterized in having (i) a broad conduction electron band (or bands) and (ii) a low effective mass, and (2) magnetic species, wherein the spins of the magnetic species are correlated at relatively long distances. Preferably, the spins are magnetically ordered ferromagnetically.

The compositions and structures have a ratio of the exchange interaction between the free electrons and the spins (J) and the bandwidth of the free electrons (W) in the range from substantially 0.5≦J/W≦5. While the range from substantially 0.5≦J/W≦5 is preferred, the range from 0.7 to 3 is more preferred.

By the way of example, the metals may include the noble metals, e.g., Cu, Au, and Ag, the alkali metals (e.g., Li, Na, and K) and aluminum. The magnetic species may include those with unfilled 3d shells, e.g., Sc, Ti, V, Cr, Mn, Fe, Co, Ni, Cu, and Zn, those with unfilled 4f shell, e.g., Lanthanides and Rare Earths (unpaired 4f states), or those with unfilled 5f shells, e.g. actinides.

The materials need not have a ‘lattice’ and so the use of the term lattice spacing should be considered by analogy for an identifiable material.

While not limited to this range, useful superconductive structures may include magnetic species in an amount ranging from substantially 5% to 20% atomic concentration.

Extremely high critical temperatures (T_{c}) may be achieved, including materials with T_{c} preferably at or greater than substantially 150 K, more preferably at or above 0 C, and even more preferably at substantially ambient temperatures or higher, e.g., 100 C.

Given the high critical temperature of these superconductors, they may be used in any variety of application. Application range from Energy Storage to Energy Transmission, imaging technologies, e.g., structural analysis, crack location, electronics, e.g., Converters (A/D, D/A), logic, interconnects and microwave circuits, including filters, and transportation systems such as magnetically levitated systems, as well as use in superconducting detectors, e.g., SQUIDs.

The inventions disclosed herein comprise a series of both compositional and structural techniques for achieving the desired superconductors. Specifically, those solutions effectively combine a metal having broad conduction electron band and low effective electron mass, such as noble metals, with magnetic species, wherein the magnetic moments have long range ferromagnetic correlation. The techniques permit the material to be ‘tuned’ so as to achieve these necessary and desirable properties, thereby more easily achieving the desired superconductor. In the preferred embodiment, the resulting concentration of magnetic atoms is preferably at the 5-20% level.

In order to tune the properties, in particular the magnetic exchange interaction and conduction bandwith, these inventions address the solid solubility of the magnetic species and optionally the dilution of the magnetic species with a third element. These solutions lead to more complicated structures, including ternaries as well as more open materials. Preferably, these materials can incorporate additional elements, preferably intercalcated, such as hydrogen, carbon or nitrogen.

Within the parameters of these inventions are various classes of alloys, one know as Heusler-related alloys and another denominated Laves alloys. They will be addressed in turn.

As to the Heuslar-related alloys, they often have large range of solid solubilities and can consist of metal, magnetic atoms and also another element to “dilute” the magnetic material in either an ordered or random fashion. An example would be Au₂(Mn,Z)₂ where Z can be Al, Ga, In, Cu. Also Cu can be exchanged for Au on the X sites to give be Cu₂(Mn, Z)₂. This allows for large range in tuning as demonstrated, with reference to FIG. 6, by the variation of Neél temperature with changing Mn/Z ratio.

Within the scope of this invention, the following superconductive composition may be used:
N₂(MₓZ_{y})₂
where N is a metal, the metal characterized in having;
(i) broad conduction electron band and
(ii) low effective electron mass, and
   where M comprises one or more magnetic species;
      Z is a non-magnetic diluent to the magnetic species,
      wherein x+y are substantially 1, and
      wherein magnetic moments of the magnetic species are correlated over a relatively long range.

In one embodiment, N is a Noble Metal., and preferable copper, gold or silver. Alternatively, N could be an Alkali Metal, such as Li, Na, K. Alternatively, N may be aluminum.

In one embodiment, M includes elements with unfilled 3d shells, such as Sc, Ti, V, Cr, Mn, Fe, Co, Ni, Cu, and Zn. In another embodiment, M includes elements with unfilled 4f shells, such as the Lanthanides or Rare Earths. Alternatively, M may include elements with unfilled 5f shells, such as the Actinides.

One preferred embodiment is Au₂Mn_{2-z}Al_{z}, where x is in the range from substantially 0.1≦z≦5, preferably 0.3. Alternately, this can be represented as Au₂(MnₓAl_{y})₂ where x+y is substantially 1, and y is in the range from substantially 0.05≦y≦0.25, preferably 0.15.

The L2₁ structure of the Heusler alloys is shown in FIG. 4 where in this case the Y atoms are ordered and are shown as the magnetic species (magnetic moments are shown) and are ferromagnetically ordered. The Y and Z atoms could be disordered in which case the Y and Z sites would be the same. As more Z atoms are incorporated into the structure at the expense of the Y atoms the magnetic content on those sites would be diluted.

FIG. 5 shows a structure of a Laves alloy usable with these inventions. Laves phases (designated XY₂, see MgCu₂) are also attractive because they can be made from a large range of intermetallics and also can accommodate a large fraction of hydrogen in the lattice. They are usually formed when combining a small and large atom. Generally, the comments herein applicable to the Heusler-like alloys apply to the Laves-like alloys, however, in the Laves-like alloys the magnetic species can be on either the X or Y sites. The structure may include a third element for diluent purposes, such as aluminum, gallium or silicon.

These inventions possess the ability to manipulate both the metallic properties, while maintaining a wide band gap, the magnetic properties and also the magnetic structure. This has been shown effectively (by following TN) for the Heulser alloys (shown in the FIG. 6 for Au₂(Mn, Zn)₂). Optionally, a composition and structure having the properties designated by “X” on FIG. 6, where TN has effectively moved to 0 K with a finite magnetic correlation length, which may not be stable. The neighboring and short range magnetic moments may be correlated antiferromagnetically or ferromagnetically, but preferably the relatively long range magnetic moments are correlated ferromagnetically. Short range within the context means approximately 10 lattice spacings, or about 40 Å. When the magnetic moments are correlated ferromagnetically in the short term, the composition preferably has no Curie temperature. Preferably, the relatively long range for correlation between magnetic moments is approximately 100 lattice spacings, or about 400 Å.

Intercalation of hydrogen, carbon or nitrogen may be used to change the magnetic properties. These will offer a convenient method for fine-tuning the key parameters. Intermetallics having the correct conduction bandwith and magnetic interactions may be used, but the long range correlations are tuned using twin transformation. This is relying on changing the correlations by magneto-striction transformation such as is possible in the Heusler related alloys which are being investigated for their shape memory properties. Then it could be combined with a “re-etched” substrate which affects long range magnetic correlation. By the way of example, a stepped substrate, wherein the step size is on the order of the long range correlation, e.g., 400 Å, may promote or tune long range correlation. Optionally, a stepped substrate may be made by etching of the steps. Steps may be easily etched in a silicon substrate.

In yet another aspect, the composition may be formed into particles having a size from substantially 40 to 400 Å. The particles are then agglomerated. The particles may be agglomerated in a random fashion or an ordered fashion. By the way of example, 40-400 Angstrom particles of metal/magnetic species and possibly diluent of the magnetic species as non-crystals prepared by: sol/colloid route, laser, flash vaporization. These particles are then pressed/agglomerated. It is desirable to control the boundaries at the particle interface. Thiols to terminate the particles of some nanoparticles have been shown to self assemble into regular 2D and 3D arrays on surfaces. This could be a means to minimize the boundaries. The thiol termination would be removed after the assembly process.

Clusters grown in mesoporous materials (preferably 3D mesopores) are another option, where the clusters are of the correct material combination of metal, magnetic species and possibly diluent of the magnetic species to create the correct particle properties. The mesopores must be of the right dimensions to allow growth of clusters to the correct sizes (40-400A).

In yet another aspect of this invention, the superconductive composition may further include a host or leave in and test. The properties in the host will likely depend upon the interactions between clusters, as there needs to be a connection to allow for the flow of the electrons.

In a thin film, it may be desirable to adjust the thin film to a thickness which achieves the desired long range correlation, such as where the film is at least 400 Å thick.

Thin film multilayers may be used to tune the long range order. While possible, it is generally more difficult to constrain the other dimensions, though micropits or other structures may be used. For at least certain formats, a substrate will support the composition. For example, thin films of the superconductor would be formed on a substrate. For many applications, e.g., electronics, it is desired that the structure of the superconductive material be epitaxial to the substrate.

Optionally, steps may be taken to stabilize the composition in a desired phase. For example, by growing a thin film epitaxially (see Cu₂(Mn, Z)₂ thin films grown on MgO and sapphire at ˜450 C), phase stability may be achieved.

The thin film should again have the right combination of metal, magnetic species and possibly diluent to the magnetic species. By constraining the thin film the correlations of the magnetic moments is interrupted in one dimension which may disrupt correlations in the plane of the substrate.

### REFERENCES CITED

The following references cited in the Detailed Description are incorporated herein in full by reference.
[3] J. A. Hertz, Phys. Rev. B 14, 1165-1184 (1976)
[4] A. J. Millis, Phys. Rev. B 48, 7183 (1993).
[5] A. V. Chubukov and D. L. Maslov, Phys. Rev. B 68, 155113 (2003).
[6] P. Schlottmann, Phys. Rev. B 68, 125105 (2003).
[7] Q. Si, S. Rabello, K. Ingersent and J. L. Smith, Phys. Rev. B 68, 115103 (2003).
[8] S. Sachdev and T. Morinari, Phys. Rev. B 66, 235117 (2002).
[9] Z. Wang, W. Mao and K. Bedell, Phys. Rev. Lett. 87, 257001 (2001).
[10] V. P. Mineev and M. Sigrist, Phys. Rev. B 63, 172504 (2001).
[11] M. J. Lercher and J. M. Wheatly, Phys. Rev. B 63, 12403 (2001).
[12] J. R. Schrieffer, J. Low Temp. Phys. 99, 397 (1995).
[13] J. R. Schrieffer Superconductivity (Academic Press, 1962).
[15] J. M. Ziman, Electrons and Phonons (Oxford Press, 1954).

These inventions have been described in some detail by way of illustration and example for purposes of clarity and understanding, it will be readily apparent to those of ordinary skill in the art in light of the teachings of this invention that certain changes and modifications may be made thereto without departing from the spirit or scope of the appended claims. The compositional solutions and the structural solutions may be used separately or in combination.

What is claimed is:

1. A superconductive composition having the formula:
N₂(MₓZ_{y)}₂
where N is a metal, the metal characterized in having;
(i) broad conduction electron band and
(ii) low effective electron mass
M comprises one or more magnetic species;
Z is a non-magnetic diluent to the magnetic species,
wherein x+y are substantially 1, and wherein magnetic moments of the magnetic species are correlated over a relatively long range.

2. The superconductive composition of claim 1 wherein the magnetic moments are correlated ferromagnetically.

3. The superconductive composition of claim 1 wherein the composition has no Curie temperature.

4. The superconductive composition of claim 1 wherein N is a Noble Metal.

5. The superconductive composition of claim 6 wherein the noble metals are chosen from the group consisting of copper, gold and silver.

6. The superconductive composition of claim 1 wherein N is Alkali Metal.

7. The superconductive composition of claim 6 wherein the Alkali Metal is chosen from the group consisting of Li, Na, K.

8. The superconductive composition of claim 1 wherein N is aluminum.

9. The superconductive composition of claim 1 wherein M includes elements with unfilled 3d shells.

10. The superconductive composition of claim 9 wherein the elements with unfilled 3d shells are chosen from the group consisting of Sc, Ti, V, Cr, Mn, Fe, Co, Ni, Cu, and Zn.

11. The superconductive composition of claim 1 wherein M includes elements with unfilled 4f shells.

12. The superconductive composition of claim 11 wherein the elements with unfilled 4f shells are Lanthanides.

13. The superconductive composition of claim 11 wherein the elements with unfilled 4f shells are Rare Earths.

14. The superconductive composition of claim 1 wherein M includes element with unfilled 5f shells.

15. The superconductive composition of claim 14 wherein the elements with unfilled 5f shells are Actinides.

16. The superconductive composition of claim 1 where N is Au, M is Mn, Z is Al, and y is between approximately 0.05 and 0.25.

17. The superconductive composition of claim 16 where y is approximately 0.15.

18. The superconductive composition of claim 1 wherein the critical temperature (T_{c}) is greater than substantially 77 K.

19. The superconductive composition of claim 1 wherein the range is greater than approximately 400 Å.

20. The superconductive composition comprising in combination;
a metal, the metal characterized in having;
(i) broad conduction electron band and
(ii) low effective electron mass, and
one or more magnetic species
characterized in that the magnetic moments of the magnetic species are ferromagnetically correlated, and a structure to induce long range correlation of the magnetic species.
